(19) United States
(12) Patent Application Publication
(10) Pub. No.: US 2010/0123527 A1
(43) Pub. Date: May 20, 2010

(54) NETWORK TRANSFORMER TO REDUCE ELECTROMAGNETIC INTERFERENCE

(76) Inventor: Hsiao-Chi Yu, Taipei County (TW)

Correspondence Address: Muncy, Geissler, Olds & Lowe, PLLC, P.O. BOX 1364, FAIRFAX, VA, 22038-1364, US

(21) Appl. No.: 12/274,830

(22) Filed: Nov. 20, 2008

(51) Int. Cl. H04B 3/28; H03H 7/09

(52) U.S. Cl. 333/12; 333/177; 333/24 R

(57) ABSTRACT

A network transformer to reduce electromagnetic interference (EMI) is connected to two network equipment to transmit data. It has a transformation unit to transform input power and input information of one network equipment to output power and output information and a plurality of high frequency signal attenuation elements to receive the output power and output information and reduce high frequency noises thereof. The attenuated output information and output power are sent to the load of the other network equipment. The high frequency signal attenuation elements and the load are bridged by high frequency signal channel elements which receive high frequency signals of the output information and output power, and integrate and ground the high frequency signals. Therefore, the high frequency signals are eliminated and EMI is reduced.

### FIELD OF THE INVENTION

The present invention relates to a network transformer and particularly to a network transformer to reduce electromagnetic interference (EMI).

### BACKGROUND OF THE INVENTION

A conventional network transformer usually is installed between a client interface and a network transceiver chip to transmit data to other ends connected to a network through coupling of internal electromagnetic field. It also has internal coils coupled to do filtering to boost signal intensity to prevent different voltages or currents to pass through different network equipment to cause damages of the equipment resulting from network connection.

Refer to FIG. 1 for a conventional network transformer and its circuit structure. The network transformer 100 has a transformation unit 200, a choke coil 300 connecting to the transformation unit 200 and an induction coil 400 connecting to the choke coil 300. The transformation unit 200 receives input power S100 and input information S101 from network equipment (not shown in the drawing) and transforms to generate output power S200. The induction coil 400 induces and generates output information S201 so that AC power of the output power 200 is blocked by the choke coil 300, and the output power S200 and output information S201 are sent together to another network equipment (not shown in the drawing). Therefore, information can be transmitted and electric power also can be transformed.

Although the conventional network transformer 100 can transmit information and transform electric power, it cannot isolate high frequency signals of the output power S200 and output information S201. The high frequency signals generate electromagnetic radiation and results in EMI.

### SUMMARY OF THE INVENTION

Therefore, the primary object of the present invention is to solve the aforesaid disadvantage by eliminating the high frequency signals to reduce EMI.

The present invention provides a network transformer to reduce EMI. It is connected to two network equipment to transmit data. It has a transformation unit, a plurality of high frequency signal attenuation elements electrically connected to the transformation unit and a plurality of high frequency signal channel elements connecting to the high frequency signal attenuation elements. The transformation unit transforms input power and input information of one network equipment to output power and output information, and sends the output power and output information to the high frequency signal attenuation elements to reduce high frequency noises of the output information and output power. Then the attenuated output information and output power are transmitted to the load of the other network equipment. By bridging the high frequency signal channel elements between the high frequency signal attenuation elements and the load, high frequency signals of the output information and output power can be integrated and grounded through the high frequency signal channel elements. Thus the high frequency signals can be eliminated, and EMI can be reduced.

In short, the invention provides the high frequency signal attenuation elements to attenuate the high frequency signals of the output power and output information, and integrate and ground the attenuated output power and output information of high frequency signals through the high frequency signal channel elements. Hence the load received the output power and output information is not affected by the high frequency signals. And EMI also can be reduced.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic circuit diagram of a conventional network transformer.

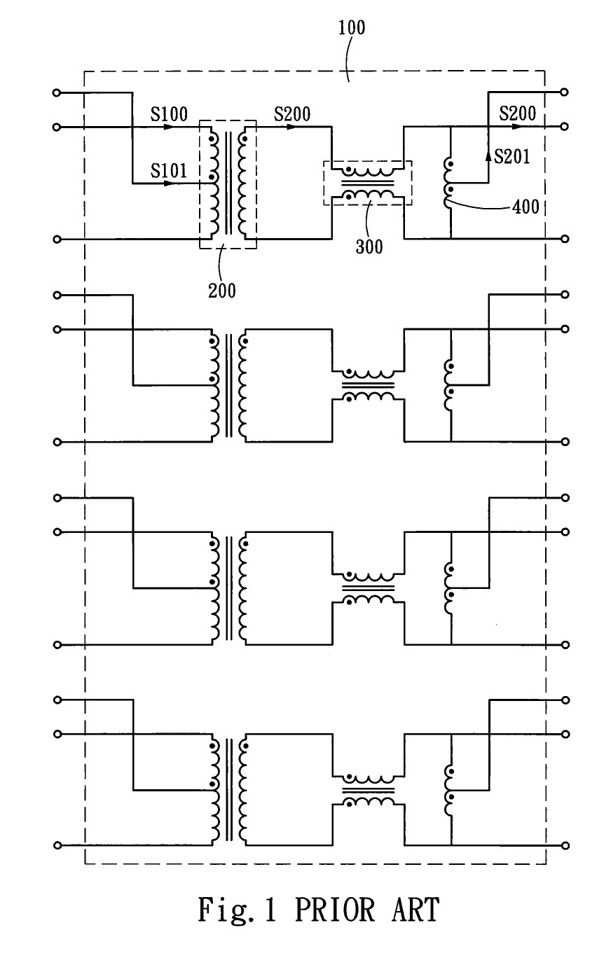

FIG. 2 is a schematic circuit diagram of a first embodiment of the invention.

FIG. 3 is a schematic circuit diagram of a second embodiment of the invention.

### DETAILED DESCRIPTION OF THE PREFERRED EMBODIMENTS

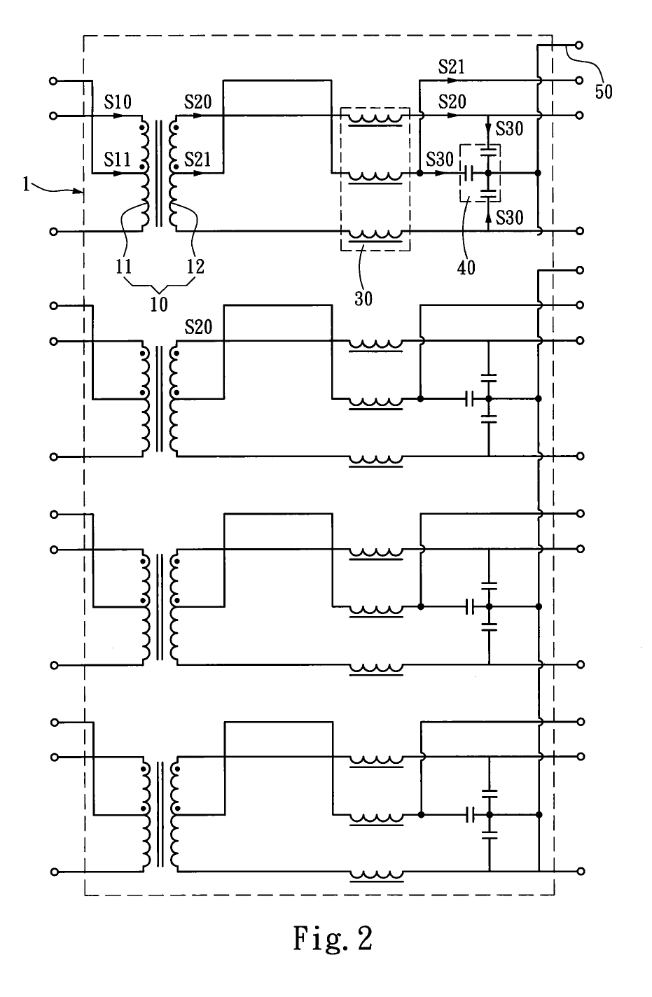

Please refer to FIG. 2, the network transformer 1 to reduce EMI according to the invention has a plurality of pins at two sides connecting to two network equipment (not shown in the drawing) to transmit data. It includes a transformation unit 10, a plurality of high frequency signal attenuation elements 30 and a plurality of high frequency signal channel elements 40. The transformation unit 10 receives input power S10 and input information S11 from one network equipment (not shown in the drawing) and transforms them to output power S20 and output information S21. The high frequency signal attenuation elements 30 are electrically connected to the transformation unit 10, and receive the output power S20 and output information S21, and reduce high frequency noises of the output information S21 and output power S20. Then the attenuated output information S21 and output power S20 are transmitted to the load of the other network equipment (not shown in the drawing). The high frequency signal channel elements 40 are installed between the high frequency signal attenuation elements 30 and the load to receive high frequency signals S30 of the output information S21 and output power S20, and integrate and ground the high frequency signals S30. Therefore, the high frequency signals can be eliminated, and EMI also can be reduced.

The transformation unit 10 has a primary coil 11 and a secondary coil 12. The primary coil 11 receives the input power S10 and input information S11, and the secondary coil 12 induces the output power S20 and output information S21. The output power S20 and output information S21 are transmitted from the secondary coil 12 to the high frequency signal attenuation elements 30 which are inductors in this embodiment to reduce the high frequency noises of the output power S20 and output information S21, especially the noises between 30 MHz and 3 GHz. Thus radiation waves generated by the high frequency noises can be greatly reduced. Then the attenuated output power S20 and output information S21 are transmitted to the load of the other network equipment. The high frequency signal channel elements 40 are coupled in parallel with a channel linking the high frequency signal attenuation elements 30 and the load. The network transformer 1 has a ground pin 50 connecting to the high frequency signal channel elements 40. In this embodiment, the high frequency signal channel elements 40 are capacitors of a high frequency and low impedance. Hence the high frequency signals S30 are transmitted to the high frequency signal channel elements 40 and isolated before the attenuated output power S20 and output information S21 are sent to the load. Then the high frequency signals S30 of the output power S20 and output information S21 are integrated and grounded through the high frequency signal channel elements 40.

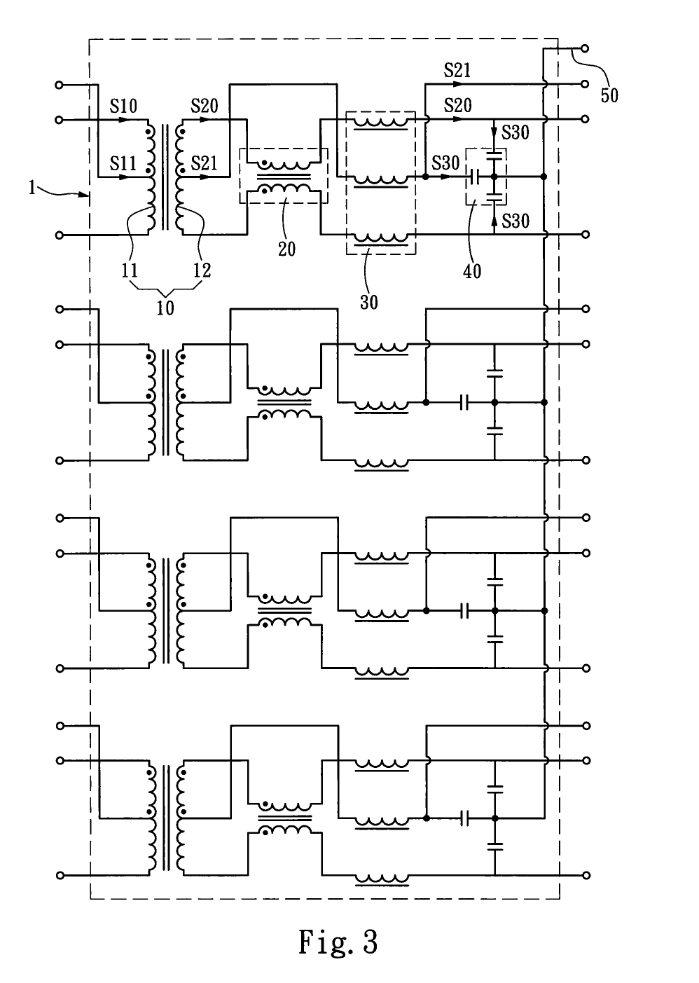

Moreover, in response to different information transmission requirements of the network equipment, another embodiment of the invention can be provided as shown in FIG. 3. In this embodiment, the network transformer 1 includes a choke coil 20 connecting to the transformation unit 10 and high frequency signal attenuation elements 30. The transformation unit 10 has a primary coil 11 to receive input power S10 and input information S11, and a secondary coil 12 to generate output power S20 and output information S21. The output power S20 is transmitted to the choke coil 20 to block AC power of the output power S20. Then the output power S20 and output information S21 pass through the high frequency signal attenuation elements 30 to reduce high frequency noises thereof, thereafter are sent to the load of the other equipment. Through the high frequency signal channel elements 40, the high frequency signals S30 of the output power S20 and output information S21 are integrated and transmitted to the ground pin 50 and the high frequency signals S30 to be isolated.

As a conclusion, the invention mainly provides high frequency signal attenuation elements 30 to reduce high frequency noises of output power S20 and output information S21, and high frequency signal channel elements 40 to integrate and ground high frequency signals S30 of the attenuated output power S20 and output information S21. Therefore, the load receiving the output power S20 and output information S21 is not affected by the high frequency signals S30, and EMI can be reduced.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A network transformer to reduce electromagnetic interference connecting to two network equipment to transmit data, comprising:
a transformation unit to transform input power and input information of one network equipment to output power and output information;
a plurality of high frequency signal attenuation elements electrically connected to the transformation unit to receive the output power and the output information and reduce high frequency noises of the output power and the output information, and transmit the output power and the output information to a load of the other network equipment; and
a plurality of high frequency signal channel elements bridging the high frequency signal attenuation elements and the load to receive high frequency signals of the output information and the output power and integrate and ground the high frequency signals.

2. The network transformer of claim 1 further having a choke coil connecting to the transformation unit and the high frequency signal attenuation elements to receive the output power and isolate AC power of the output power.

3. The network transformer of claim 1, wherein the high frequency signal attenuation elements are inductors.

4. The network transformer of claim 1, wherein the high frequency signal channel elements are capacitors.

5. The network transformer of claim 1 further having a ground pin connecting to the high frequency signal channel elements.
